(19) United States
(12) Patent Application Publication
(10) Pub. No.: US 2019/0243079 A1
(43) Pub. Date: Aug. 8, 2019

(54) FLIP CHIP PHOTODETECTOR BY USING PLATING AU PILLARS METHOD

(71) Applicant: LuxNet Corporation, Zhongli City (TW)

(72) Inventors: Kuo-Hao LEE, Zhongli City (TW); Tsung-Chi HSU, Zhongli City (TW); Ming-Chih LAI, Zhongli City (TW)

(21) Appl. No.: 16/012,264

(22) Filed: Jun. 19, 2018

(30) Foreign Application Priority Data
Feb. 6, 2018 (TW) 107104162

(51) Int. Cl. G02B 6/42; G02B 6/43; H01L 21/56; H01L 23/498; H01L 23/00

(52) U.S. Cl. CPC G02B 6/4214; G02B 6/4206; G02B 6/43; H01L 24/29; H01L 23/49816; H01L 24/11; H01L 21/563

(57) ABSTRACT

The present invention is a flip-chip photodetector, comprising a carrier and a back-illuminated chip having a central portion and a peripheral portion, wherein the central portion has a greater thickness than the peripheral portion; the peripheral portion is provided with a plurality of metal pillars connected to the carrier, and the back illuminated chip is connected to the carrier by the plurality of metal pillars; further, the plurality of the metal pillars are provided on the back-illuminated chip by electroless plating.

### 1. TECHNICAL FIELD

The present invention relates to a flip-chip photodetector and a method for making the Au pillars on photodetector.

### 2. DESCRIPTION OF RELATED ART

Flip-chip photodetectors are used in optical communication to receive optical signals and convert them into electric current. The main structures of a flip-chip photodetector are an optoelectronic chip, a carrier, and a base. In earlier times, each electrode of the optoelectronic chip was connected to the corresponding electrode of the carrier by a lead, so a great variety of mounting elements (e.g., electrode pads) were required for the assembly of the flip-chip photodetector. Recently, with compactness and miniaturization being the trend of electronic products, the flip-chip packaging method was developed to downsize chip packages. The flip-chip technique involves providing each electrode of an optoelectronic chip with a metal bump and then directly connecting each metal bump to the corresponding electrode of the carrier without using leads. In the past, when leads were used, it was important that each lead have an appropriate length to prevent parasitic inductance, and in order to prevent parasitic inductance, the provision of mounting elements was also subject to limitations. The flip-chip technique, on the other hand, can lower impedance, keep optical signals from distortion during transmission, and reduce the use of leads and related elements to downsize the resulting chip packages.

The optoelectronic chip of an flip-chip photodetector made with the flip-chip packaging method is known as a back-illuminated chip because the optoelectronic chip is inverted, with the electrodeless side of the chip substrate serving as the light-receiving side and the electrode side of the substrate facing the carrier. The electrodes of the optoelectronic chip are respectively connected to the corresponding electrodes of the carrier via metal bumps or gold balls to enable electrical conduction and reception of optical signals. Generally, metal bumps and gold balls are provided on the carrier by electric welding, electroplating, vapor deposition, or a gold ball mounting method. Electric welding and electroplating are particularly suitable when relatively high metal bumps are used.

### BRIEF SUMMARY OF THE INVENTION

However, providing metal bumps or gold balls to a back-illuminated chip may present problems. For example, an optoelectronic chip may crack when metal bumps or gold balls are provided thereto by electric welding. If electroplating is used instead, the high-concentration heavy metals and organic solvents in the plating solution may pollute the environment and endanger human health. Vapor deposition and gold ball mounting require expensive apparatuses and a huge amount of gold such that the costs of manufacturing equipment and materials are high. In short, the production of the flip-chip photodetector chip with back-illuminated chip is currently disadvantaged by potential environmental pollution and elevated equipment and material costs.

To solve the aforesaid problems of the prior art, the inventor of the present invention aimed to provide an flip-chip photodetector with back-illuminated chip whose manufacture is environmentally friendly, safe, and low-cost, and which uses relatively high metal pillars to keep the optoelectronic chip from being compressed, and hence from cracking, during the packaging process of the flip-chip photodetector.

The objective of the present invention is to provide a flip-chip photodetector comprising a carrier and a back-illuminated chip. The back-illuminated chip has a central portion and a peripheral portion, wherein the central portion has a greater thickness than the peripheral portion, and the peripheral portion is provided with a plurality of metal pillars connected to the carrier; wherein the metal pillars have heights greater than the thickness of the central portion of the back-illuminated chip.

Furthermore, the metal pillars are provided on the back-illuminated chip by electroless plating, and at least two of the metal pillars are respectively connected between corresponding electrodes of the back-illuminated chip and corresponding electrodes of the carrier.

The another objective of the present invention is to provide a method for making an optoelectronic device having a plurality of metal pillars, comprising the steps of: providing a back-illuminated chip, wherein the back-illuminated chip has a central portion and a peripheral portion, and the central portion has a greater thickness than the peripheral portion; and providing the plurality of metal pillars on the peripheral portion of the back-illuminated chip by electroless plating, wherein the metal pillars have heights greater than the thickness of the central portion of the back-illuminated chip.

Furthermore, at least two of the metal pillars are connected to electrodes of the back-illuminated chip.

Another objective of the present invention is to provide a method for making a flip-chip photodetector, comprising the steps of: providing a carrier; providing the optoelectronic device made by the above method; and connecting the metal pillars of the back-illuminated chip to the carrier.

Furthermore, at least two of the metal pillars connected on the back-illuminated chip are connected to electrodes of the carrier.

Furthermore, the metal pillars are gold.

Furthermore, the thickness of the central portion of the back-illuminated chip is 5˜10 μm, and the height of the metal pillars are greater than 7˜15 μm.

As above, the flip-chip photodetector disclosed herein has a back-illuminated chip with a relatively thick central portion and is provided with a plurality of metal pillars so that the back-illuminated chip will not break due to compression after it is provided on a carrier and packaged. In addition, the methods disclosed herein for making an optoelectronic device having a plurality of metal pillars and for making a flip-chip photodetector use electroless plating (also known as chemical plating) to provide metal pillars to the electrodes of a back-illuminated chip. The disclosed methods, therefore, have such advantages as environmental friendliness, safety, and low cost over electric welding, electroplating, vapor deposition, and gold ball mounting and are suitable for industrial application.

### BRIEF DESCRIPTION OF THE SEVERAL VIEWS OF THE DRAWINGS

FIG. 1 is a perspective view of a flip-chip photodetector according to the present invention;

FIG. 2 is a perspective view of a back-illuminated chip according to the invention;

FIG. 3 is a side view of the back-illuminated chip in FIG. 2;

FIG. 4 is a perspective view showing the back-illuminated chip in FIG. 2 provided with a plurality of metal pillars to become an optoelectronic device with metal pillars;

FIG. 5 is a side view of the back-illuminated chip with metal pillars (i.e., the optoelectronic device with metal pillars) in FIG. 4; and

FIG. 6 is a perspective view of a carrier according to the invention.

### DETAILED DESCRIPTION OF THE INVENTION

The terms “comprising” or “includes” as used in the present invention means not excluding the presence or addition of one or more other components, steps, operations and/or elements to the described components, steps, operations and/or elements. “One” means that the object has one or more grammatical objects (i.e. at least one).

The details and technical solution of the present invention are hereunder described with reference to accompanying drawings. For illustrative sake, the accompanying drawings are not drawn to scale. The accompanying drawings and the scale thereof are restrictive of the present invention.

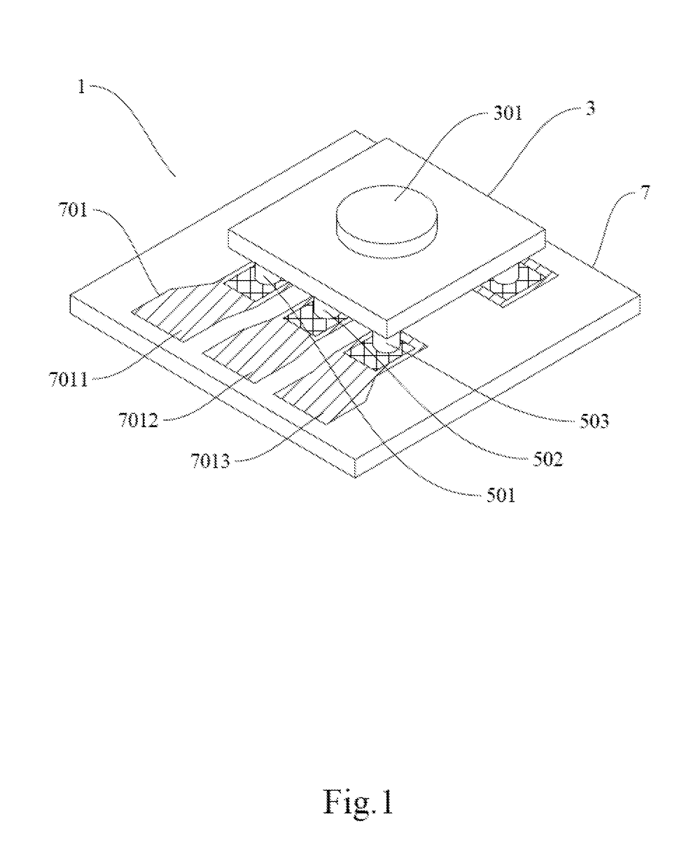

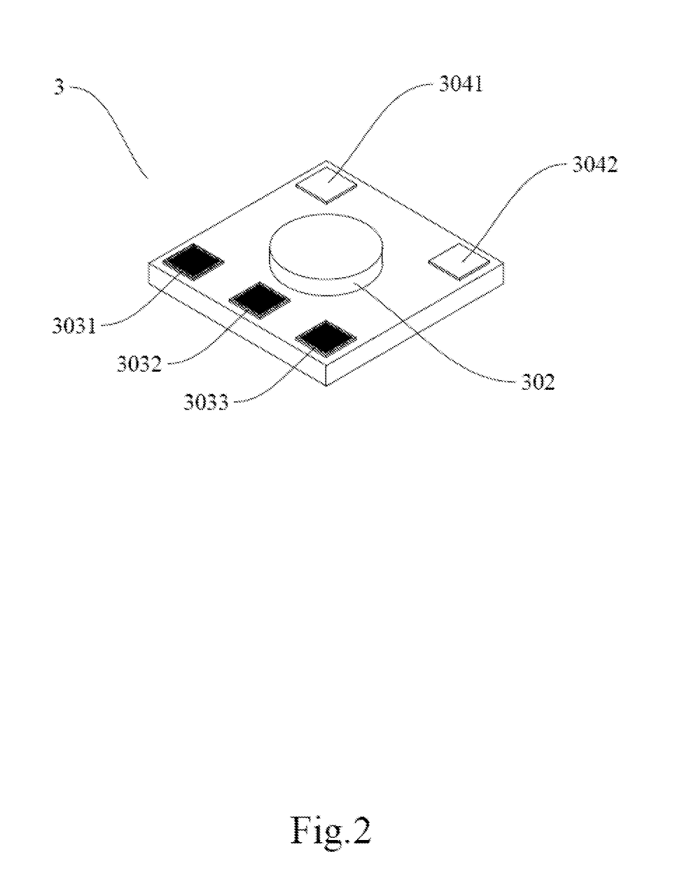

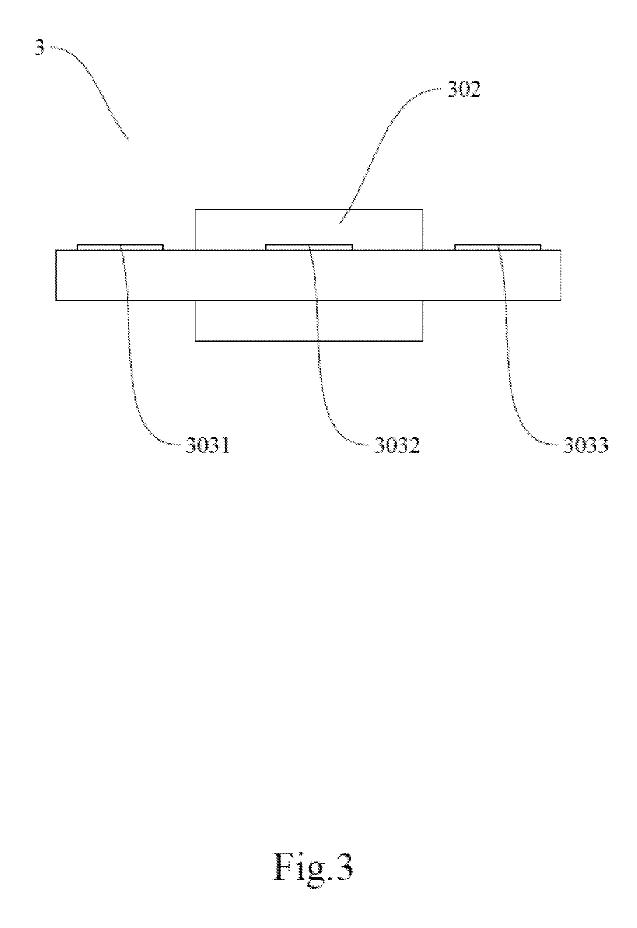

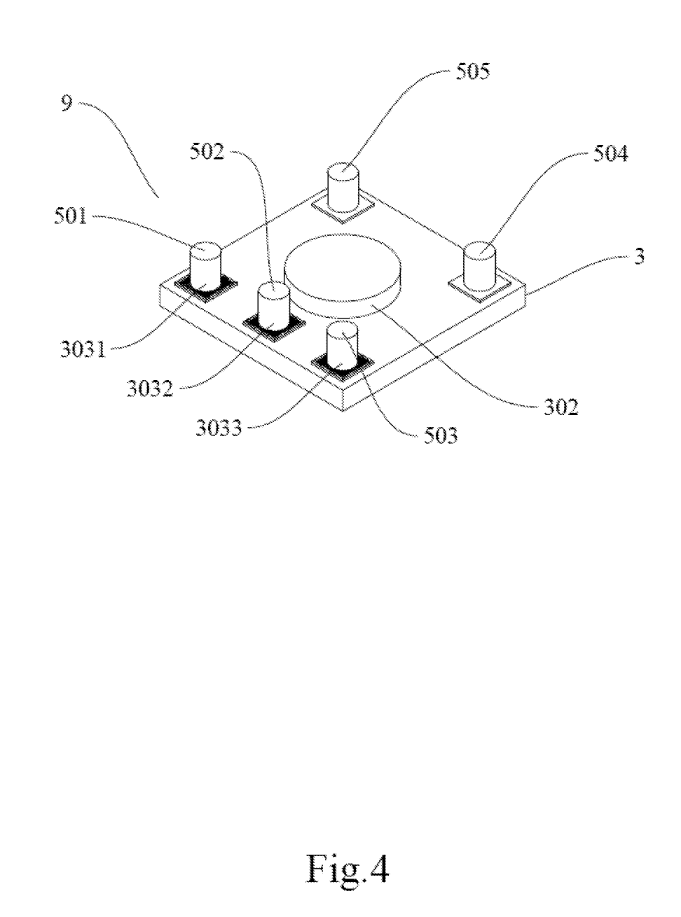

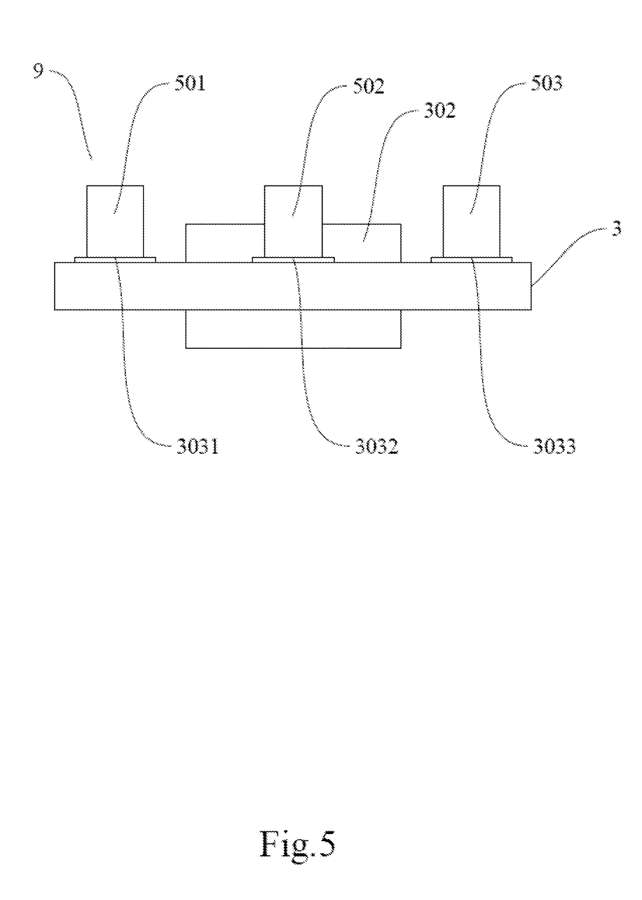

Referring to FIG. 1 for a flip-chip photodetector 1 according to the present invention, the flip-chip photodetector 1 includes a carrier 7 and a back-illuminated chip 3. As shown in FIG. 2 and FIG. 3, the central portion 302 of the back-illuminated chip 3 is thicker than the peripheral portion of the back-illuminated chip 3 so that the p-electrode and the n-electrode of the back-illuminated chip 3 can be provided on the same side. When the back-illuminated chip 3 is provided with a plurality of metal pillars 501˜505 as shown in FIG. 4 and FIG. 5, it is the peripheral portion of the back-illuminated chip 3 that is provided with the metal pillars, and the heights of the metal pillars 501˜505 are greater than the thickness of the central portion 302 of the back-illuminated chip 3. During the packaging process, therefore, the peripheral portion of the back-illuminated chip (i.e., where the metal pillars are provided) will be elevated to facilitate bonding, and after packaging, the central portion of the back-illuminated chip 3 will not be under compression, which if happening may break the back-illuminated chip. The metal pillars 501˜505 are provided on the back-illuminated chip 3 by electroless plating. More specifically, the metal pillars 501, 502, and 503 are respectively provided on the electrodes 3031, 3032, and 3033 of the back-illuminated chip 3; the opposite ends of the metal pillars 501, 502, and 503 are connected to the electrodes 701 of the carrier 7 respectively, as shown in FIG. 1; and the metal pillars 504 and 505 are not connected to any electrodes and therefore do not provide electrical conduction, serving mainly as a counterweight when the back-illuminated chip 3 is provided on the carrier 7. Once the flip-chip photodetector 1 is provided in a optoelectronic module, electrical conduction between the flip-chip photodetector 1 and the optoelectronic module can be achieved through the electrodes 701 of the carrier 7 so that, with the metal pillars 501, 502, and 503 connected respectively to the electrodes 3031, 3032, and 3033, the back-illuminated chip 3 can receive optical signals through the light-receiving portion 302 and convert the optical signals into electric current.

The present invention also provides a method for making a optoelectronic device having a plurality of metal pillars. The method begins by providing a back-illuminated chip 3 as shown in FIG. 2 and FIG. 3, wherein the central portion 302 of the back-illuminated chip 3 is thicker than the peripheral portion of the back-illuminated chip 3. Then, referring to FIG. 4 and FIG. 5, the peripheral portion of the back-illuminated chip 3 is provided with a plurality of metal pillars 501˜505 by electroless plating such that a optoelectronic device 9 with multiple metal pillars is obtained. More particularly, the heights of the metal pillars 501˜505 are greater than the thickness of the central portion 302 of the back-illuminated chip 3; the metal pillars 501, 502, and 503 are connected to the electrodes 3031, 3032, and 3033 of the back-illuminated chip 3 respectively in order to further connect, and thus enable electrical conduction, with other electrodes; and the metal pillars 504 and 505 are not intended for electrical conduction and therefore are not connected to any electrodes. When the optoelectronic device 9 with multiple metal pillars is provided on a substrate or carrier, the metal pillars 504 and 505 help balance the weight of the optoelectronic device 9.

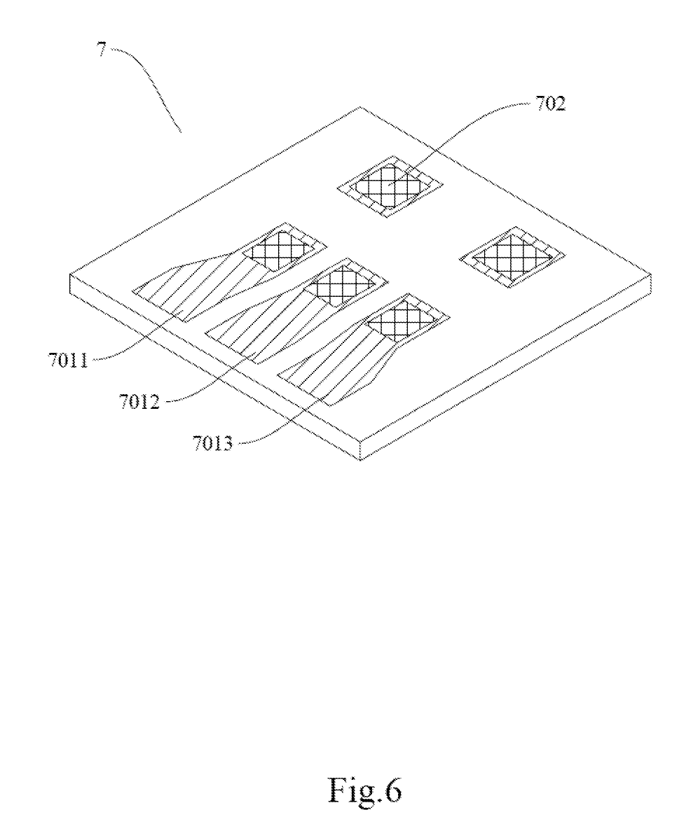

The present invention further provides a method for making a flip-chip photodetector. First, a carrier 7 as shown in FIG. 6 is provided, wherein the carrier 7 has a plurality of electrodes 7011, 7012, and 7013 and a plurality of solder pads 702. Next, referring to FIG. 4 and FIG. 5, an optoelectronic device 9 with a plurality of metal pillars as made by the method described above is provided. Then, the metal pillars 501˜505 of the back-illuminated chip 3 are connected to the solder pads 702 on the carrier 7 respectively. The solder pads 702 are respectively connected with the metal pillars 501˜505 by heating.

As used herein, the term “solder pad” refers to any connecting metal commonly used for welding, such as a tin-based solder, a copper-based solder, a gold-based solder, or an alloy (e.g., a gold-tin alloy)-based solder.

As used herein, the term “back-illuminated chip” refers to a common back-illuminated or flip-chip photodiode chip whose electrodeless side is configured to receive optical signals and which can convert optical signals into electric current. Some notable examples of such chips are PN photodiodes, NPN photodiodes, PIN photodiodes, and avalanche photodiodes (APDs); the present invention has no limitation on the type of the back-illuminated chip. The central portion of the back-illuminated chip (i.e., the center of the die) has a thickness of 5˜10 μm, such as 5 μm, 5.5 μm, 6 μm, 6.5 μm, 7 μm, 7.5 μm, 8 μm, 8.5 μm, 9 μm, 9.5 μm, or 10 μm.

As used herein, the term “metal pillars” refers to any common metal material such as silver, copper, gold, aluminum, sodium, molybdenum, tungsten, zinc, nickel, iron, platinum, tin, lead, a silver-copper alloy, a cadmium-copper alloy, a chromium-copper alloy, a beryllium-copper alloy, a zirconium-copper alloy, an aluminum-magnesium-silicon alloy, an aluminum-magnesium alloy, an aluminum-magnesium-iron alloy, an aluminum-zirconium alloy, an iron-chromium-aluminum alloy, or a metal powder mixture of two or more of the foregoing; the present invention has no limitation in this regard. Preferably, the metal pillars are gold. The metal pillars may take any shape, e.g., cylinders or bumps; the present invention has no limitation in this regard, either. The heights of the metal pillars may be 7˜15 μm, such as 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, or 15 μm. The heights of the metal pillars, however, must be greater than the thickness of the central portion of the back-illuminated chip (i.e., the center of the die) to ensure that the back-illuminated chip will not break because of compression while provided on the carrier. The diameters of the metal pillars may be 40˜80 μm, such as 40 μm, 45 μm, 50 μm, 55 μm, 60 μm, 65 μm, 70 μm, 75 μm, or 80 μm, preferably 60 μm.

As used herein, the term “electroless plating” (or “chemical plating”) refers to placing a back-illuminated chip into an electroless plating solution in order for metal to deposit on the back-illuminated chip. Electroless plating may be completed at different rates, depending on temperature. In a preferred embodiment of the present invention, heating is carried out through a thermostatic water bath, and the metal pillars of the invention are formed by electroless plating at a temperature of 30˜80° C., preferably 40˜70° C. The efficiency of electroless plating, i.e., the speed at which metal deposits, varies with temperature. By controlling the duration of electroless plating, the heights of the metal pillars can be controlled. For example, a 10 μm metal pillars may take a 3-hour, 3.5-hour, 4-hour, 4.5-hour, 5-hour, 5.5-hour, 6-hour, 6.5-hour, or 7-hour electroless plating process to complete. Moreover, before the back-illuminated chip of the invention is subjected to electroless plating, a pattern transfer process is performed to expose the areas of the back-illuminated chip that are intended to be provided with metal pillars (such as areas corresponding respectively to the electrodes 3031˜3033 and the electrodeless areas 3041 and 3042 in FIG. 2) while the remaining area, which is not intended to be provided with metal pillars, is shielded with a photomask. The pattern transfer process may be conducted by any common pattern transfer technique, such as photolithography. Metal pillars will gradually grow from, or be chemically plated on, the unmasked areas after the back-illuminated chip is placed in the electroless plating solution. The electroless plating solution may be any one commonly used for metal deposition, including phosphates, sulfates, sulfites, fatty acids, benzenesulfonates, tartrates, organic acids, inorganic acids, polymeric materials, thiols, and so on, and the metal to be deposited may be gold, palladium, tin, copper, aluminum, chromium, iron, thallium, lead, bismuth, nickel, or silver, for example. To form metal pillars of gold, an electroless plating solution for depositing gold (e.g., gold sodium sulfite) should be used. To form metal pillars of copper, an electroless plating solution for depositing copper (e.g., (methyl)copper sulfate) should be used. To form metal pillars of nickel, an electroless plating solution for depositing nickel (e.g., nickel aminosulfonate) should be used. Please note that the electroless plating solution for use in the invention is not limited to the foregoing, although gold sodium sulfite is preferred.

As used herein, the term “carrier” refers to any common material that is efficient in heat dissipation (e.g., metal, ceramic, or clear glass) and that is provided with electrodes for connecting with other devices. If the carrier is metal, there will be an insulating layer (e.g., a ceramic layer) around each electrode on the carrier to prevent short-circuiting.

The flip-chip photodetector, as well as the optoelectronic device with multiple metal pillars, of the present invention can be provided in an optical communication module to receive optoelectronic signals and thus find extensive application in the field of optical communication.

In summary, the flip-chip photodetector disclosed herein has a back-illuminated chip with a relatively thick central portion and is provided with a plurality of metal pillars so that the back-illuminated chip will not break due to compression after it is provided on a carrier and packaged. In addition, the methods disclosed herein for making an optoelectronic device having a plurality of metal pillars and for making a flip-chip photodetector use electroless plating (also known as chemical plating) to provide metal pillars to the electrodes of a back-illuminated chip. The disclosed methods, therefore, have such advantages as environmental friendliness, safety, and low cost over electric welding, electroplating, vapor deposition, and gold ball mounting and are suitable for industrial application.

While the present invention has been described in connection with certain exemplary embodiments, it is to be understood that the invention is not limited to the disclosed embodiments, but, on the contrary, intended to cover various modifications and equivalent arrangements included within the spirit and scope of the appended claims and equivalents thereof.

What is claimed is:

1. A flip-chip photodetector, comprising:
a carrier; and
a back-illuminated chip having a central portion and a peripheral portion, wherein the central portion has a greater thickness than the peripheral portion, and the peripheral portion is provided with a plurality of metal pillars connected to the carrier; wherein the metal pillars have heights greater than the thickness of the central portion of the back-illuminated chip.

2. The flip-chip photodetector of claim 1, wherein the metal pillars are provided on the back-illuminated chip by electroless plating, and at least two of the metal pillars are respectively connected between corresponding electrodes of the back-illuminated chip and corresponding electrodes of the carrier.

3. The flip-chip photodetector of claim 1, wherein the metal pillars are gold.

4. The flip-chip photodetector of claim 2, wherein the thickness of the central portion of the back-illuminated chip is 5˜10 μm, and the height of the metal pillars are greater than 7˜15 μm.

5. A method for making an optoelectronic device having a plurality of metal pillars, comprising the steps of:
providing a back-illuminated chip, wherein the back-illuminated chip has a central portion and a peripheral portion, and the central portion has a greater thickness than the peripheral portion; and
providing the plurality of metal pillars on the peripheral portion of the back-illuminated chip by electroless plating, wherein the metal posts have heights greater than the thickness of the central portion of the back-illuminated chip.

6. The method of claim 5, wherein at least two of the metal pillars are connected to electrodes of the back-illuminated chip.

7. The method of claim 6, wherein the metal pillars are gold.

8. The method of claim 7, wherein the thickness of the central portion of the back-illuminated chip is 5˜10 μm, and the height of the metal pillars are greater than 7˜15 μm.

9. A method for making an optical receiver, comprising the steps of:
providing a carrier;
providing the optoelectronic device made by the method of claim 5; and
connecting the metal posts of the back-illuminated chip to the carrier.

10. The method of claim 9, wherein at least two of the metal pillars connected on the back-illuminated chip are connected to electrodes of the carrier.
